(19) United States
(12) Patent Application Publication
(10) Pub. No.: US 2004/0078508 A1
(43) Pub. Date: Apr. 22, 2004

(54) System and method for high performance data storage and retrieval

(76) Inventor: William G. Rivard, Menlo Park, CA (US)

Correspondence Address: William Rivard, 1062 Arbor Rd., Menlo Park, CA, 94025, US

(21) Appl. No.: 10/678,939

(22) Filed: Oct. 2, 2003

Related U.S. Application Data
(60) Provisional application No. 60/415,473, filed on Oct. 2, 2002.

(51) Int. Cl. G11C 5/00

(52) U.S. Cl. 711/4

(57) ABSTRACT

A new storage system architecture is described that satisfies the requirements of high availability and high performance. High performance is achieved by utilizing both parallel RAID data paths to disk and a split read and write cache. The read cache is associated with a host interface controller and the write cache is distributed over independent multi-ported write cache controllers operating within a battery protected power domain. Disk and write cache failures are survived through disk redundancy; controller redundancy provides system level survival for system faults. The system is therefore tolerant of both component and power failure, including combined component and power failure.

### CROSS-REFERENCE TO RELATED APPLICATION

This application claims priority from commonly owned co-pending provisional U.S. Patent Application No. 60/415,473 entitled “System and method for high performance data storage and retrieval” filed Oct. 2, 2002, having common inventors and assignee as this application, which is incorporated by reference as though fully set forth herein.

### FEDERALLY SPONSORED RESEARCH

None.

### FIELD OF THE INVENTION

This invention relates to data processing and storage systems.

### BACKGROUND OF THE INVENTION

Modern computing environments are in constant need of greater storage capacity, greater reliability of storage, and greater manageability of that data. This need results from the fact that computer system users are constantly creating larger, more complex data sets, and demanding more performance and reliability from their computing systems. An equally important trend shows that organizations that use computer systems are shifting their data storage strategy from a mix of online, offline, and non-managed data storage to a strategy of entirely online, fault tolerant, and managed data storage.

Centralizing data storage into a single system, or cluster of systems, provides greater manageability and greater economies of scale when purchasing storage capacity. However, a centralized data storage system must have very high performance to serve a multi-user load and exhibit exceptional reliability because down time in a centralized storage system impacts many users or organizations.

A centralized data storage system should therefore satisfy the following requirements:

(a) Have relatively high read performance: read transactions/second

(b) Have relatively high write performance: write transactions/second

(c) Preserve data integrity in the event of a failure in any device at any time

(d) Reliably conduct any transaction it acknowledges (writes)

(e) Preserve data integrity in the event of a power failure

(f) Tolerate hot-swapping of system components.

(g) Minimize vulnerability subsequent to a failure to avoid two concurrent failures.

(h) Minimize the impact of more than one failure

(i) Minimize the performance impact subsequent to a failure

(j) Minimize general maintenance requirements while maintaining reliability and performance

(k) Scale to support a large number of drives

Data processing systems, such as data storage systems that are coupled to disk drive storage media, spend a great deal of time waiting for basic read and write transactions to complete in an attached disk drive. Typically, the electronics in a storage system can process data at speeds that are orders of magnitude faster than the physical access speed of an individual disk drive. The performance of an individual disk drive can be characterized in terms of both seek time and throughput speeds.

The seek time of a disk drive determines how long it takes to initiate a read or write transaction to the disk's physical storage media and is dominated by the time it takes to move and stabilize the read/write head into position; there is an additional delay while the disk enters into the desired rotational position for a read or write operation. The throughput speed is determined by a complex combination of factors that include, but are not limited to media bit density, linear media velocity (a function of head position), media rotational velocity, track spacing, read/write electronics, and I/O interface speed. Additionally, the electronic subsystem that handles the serial bit stream(s) to and from the physical media surface(s), referred to as the “read/write channel”, has historically been and continues to be a throughput bottleneck in disk drive subsystems.

A number of strategies have been employed to mitigate some of the performance and reliability problems associated with individual hard drives. For example, the set of well known specifications, collectively referred to as “Redundant Array of Inexpensive Drives” (RAID), can be utilized to mitigate the problem of individual drive failure. Employing a RAID structure can also improve system level data read/write throughput. However, RAID techniques alone do not improve write latency (a function of seek performance). Nor does RAID address the problem of surviving a power failure or component failures other than disk drives. Another example of a technique to improve individual drive performance is that of the track cache; most commodity disk drives currently have at least 2 Megabytes to 8 Megabytes of volatile RAM built into the disk drive subsystem. A track cache loads and stores an entire track, once that track has been accessed for either a read or a write. Typically, this cache will have an aggregate storage space for several tracks; thus, as new tracks are accessed, cache entries allocated to previously accessed tracks are re-allocated to the more recently accessed tracks. For example, the least recently accessed track will be evicted when a new track is accessed. The track cache can be used to cache both read and write accesses to improve the effective disk access latency.

When a track cache entry is used to buffer a write access to the physical media, that cache entry must first be written to the physical media before that cache entry can be de-allocated and reallocated to another access. This write operation must occur to complete the previously acknowledged write transaction. Write caching in the track cache of individual disks is typically disabled in high reliability applications to prevent loss of queued, but acknowledged, write data in the event of a power failure.

The actual disk attachment interface (SCSI, ATAPI, SATA, SA-SCSI, Fiber Channel), while critical to system level performance, is subject to industry standards efforts and standards acceptance rates. These standards tend to move more slowly than other available avenues for performance improvement. Despite the general lag in individual disk drive interface performance on commodity disk drives, the most cost effective solution to building large storage systems is, in fact, to utilize commodity disk drives.

The reliability of a data storage system is primarily characterized by the system's ability to continue operating reliably at its outward facing interface(s); thus, individual component failures can be masked through redundant architectures that account for failures without an interruption in system level function. An individual disk drive's reliability can be characterized by its mean time between failures (MTBF); this number can be as low as 1 year for continuous operation of a low cost commodity disk drive. A system's reliability can be measured by mean time to data loss (MTTDL); this number should be orders of magnitude higher than that of any sub-system, such as a disk drive or controller. Current storage systems employ expensive, complex system architectures, and expensive components to achieve high system reliability; this expensive approach limits the market reach and cost effectiveness of reliable storage systems.

In addition to component failures, a reliable storage system must cope with power failures without corrupting or loosing data already acknowledged as written to disk. Complex write transaction tracking systems are typically employed to assure every acknowledged write is eventually written to the storage disk array; after a power failure and upon restoration of power, a power loss tolerant system typically enters into a recovery state until the system write-state coherence is restored.

A number of examples exist for data storage systems that attempt to satisfy the individual requirements of performance or reliability. There are also examples of systems that attempt to satisfy both requirements of performance and reliability; however these systems tend to use expensive, inefficient, or non-scalable architectures to achieve this goal.

FIG. 1 shows an example storage server system architecture consisting of a number of Storage Interface Controllers 12 that bridge the native storage interface to the central System Bus 11, through which all Storage Interface 18 data must flow. The CPU 14 coordinates the function of the system, including management of one or more Data Buffers 16 in Main Memory 15. A Data Buffer 16 can facilitate operations on storage blocks or files, or other data in a file system, database, or other storage system. The Non-Volatile RAM (NVRAM) 13 is available for storing data or state in the event of a power fault; thus, write transaction data or state information is stored in the NVRAM prior to transaction completion to physical media. Variations on this theme are taught in published reference material; these published architectures typically have the characteristic of centralizing a write cache around some NVRAM or auxiliary disk subsystem and utilizing a general purpose processor and processor memory subsystem to implement read caching. The terms “cache” and “buffer” are used interchangeably in the context of block level data access and storage.

An example of a system that addresses performance but not fault tolerance, and therefore not reliability, is the system explained by Yiming Hu and Qing Yang, “DCD—Disk Caching Disk: A New Approach for Boosting I/O Performance”, also described in U.S. Pat. No. 5,754,888. This system establishes three levels of access hierarchy between a client computing system and the disk subsystem: a small, non-volatile RAM (NVRAM) for caching writes is closest to the client computing system; a disk or disk partition that logs write data; and the mass storage disk where data is finally stored. This system operates by absorbing writes into the fast NVRAM subsystem first and then by migrating information in NVRAM to the mass storage disk via the write cache log disk. This system potentially improves write performance and addresses the problem of surviving power loss, but does not address fault tolerance of its individual components and subsystems.

A more recent architecture, also described by Yiming Hu in “RAPID-Cache—A Reliable and Inexpensive Write Cache for High performance Storage Systems” provides good write performance, accommodates a central read cache, and has a dual, centralized, asymmetric write cache. The write cache consists of two subsystems that each log all writes; the primary write cache operates at full speed and operates on the mass storage disk arrays, the backup write cache simply logs all the write operations to a separate drive in case a recovery operation is needed; either the primary or backup subsystem can fail without disrupting system operation. The RAPID-Cache can optionally utilize dual backup write caches for further redundancy. The RAPID-Cache system has an obvious cost advantage over a symmetric, fully redundant, centralized write cache system; however, the RAPID-Cache architecture has two significant problems. First, RAPID-Cache does not eliminate the need for costly NVRAM. Second, RAPID-Cache scales very poorly for large numbers of attached drives, the common case for data storage server systems.

A number of caching schemes attempt to improve performance in both read and write caches. While these existing cache strategies improve performance in a functioning system, they do not efficiently or cost effectively address the dual concerns of both high performance and high reliability in the face of component or power failure. Additionally, these existing cache schemes do not scale very well to a large number of attached drives.

### BRIEF DESCRIPTION OF THE DRAWINGS

FIG. 1 is a block diagram of the hardware system components representative of existing storage systems.

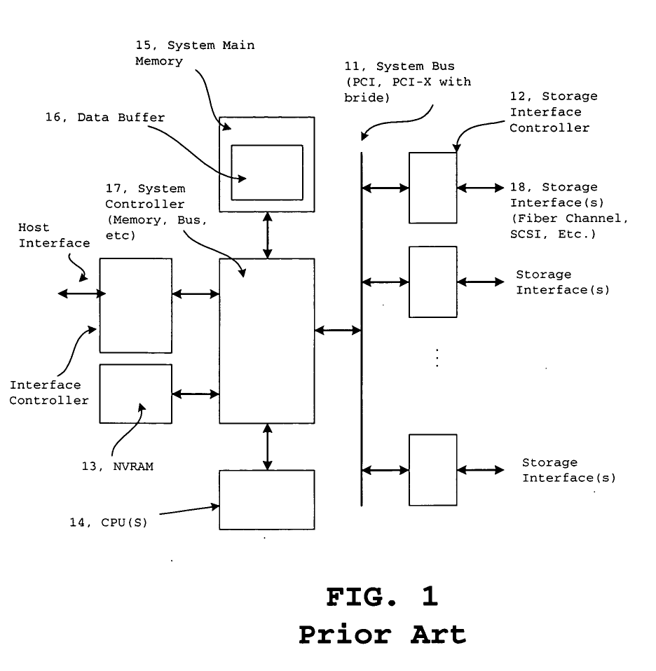

FIG. 2 is a block diagram of a multi-port read cache with a protected power domain serving a distributed write cache and disk array.

FIG. 3 illustrates a hierarchical memory architecture that allows significant amounts of memory to be attached to the read cache.

FIG. 4 illustrates two battery protected power domain architectures for fault tolerant power distribution.

FIG. 5 is a block diagram of the Write Cache Controller plus a single disk drive unit.

FIG. 6 is a flow chart of the Write Cache Controller process for handling a read, write, or general command request.

FIG. 7 is a flow chart of the Write Cache Controller process for a power shut down.

FIG. 8 is a flow chart of the Write Cache Controller process for flushing queued write requests in normal operation.

FIG. 9 is a block diagram of a Write Cache Controller implementation.

FIG. 10 shows two mechanical configurations of a Write Cache Controller attached to a hard disk drive.

FIG. 11 shows a method of clustering Cache Access Concentrators to Write Cache Controllers.

FIG. 12 is an internal block diagram of the main controller module.

### DISCLOSURE OF THE INVENTION

The present invention introduces a new storage system architecture targeted for high availability, high performance applications while maintaining cost effectiveness and flexibility. Limitations in the prior art are overcome through a novel architecture, presented herein.

It is to be understood that the present invention may be implemented in various forms of hardware, software, firmware, special purpose processors, or a combination thereof.

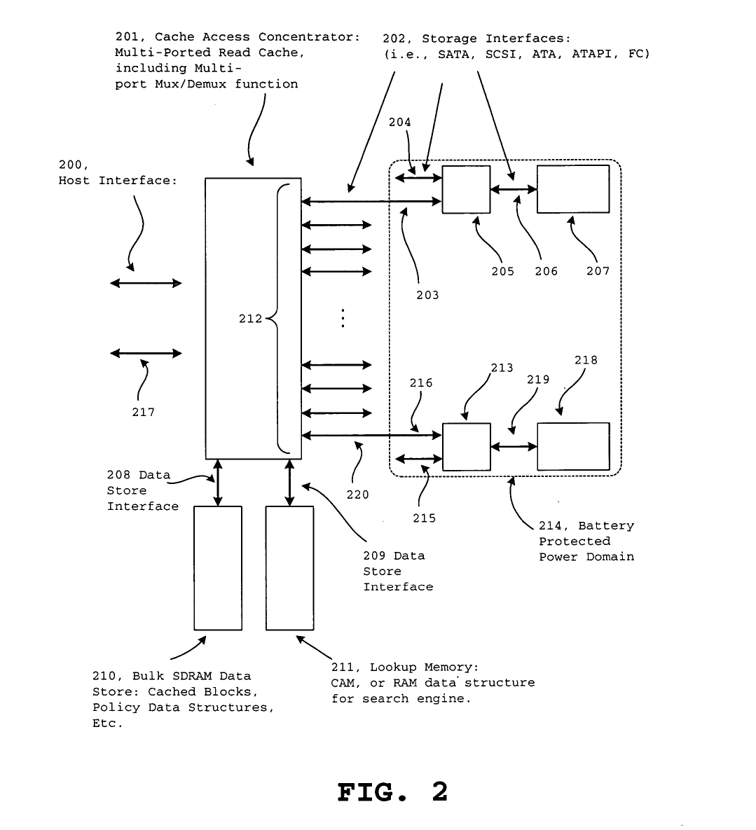

FIG. 2 shows a block diagram of the preferred embodiment of the present invention. The Host Interface 200 is preferably a high performance interface. High performance industry standard native storage interfaces include, for example, Fiber Channel (FC), SCSI, ATA, ATA-PI, SATA and SA-SCSI; industry standard system bus interfaces include, for example, PCI-X, PCI, AGP, and Sbus; high performance industry standard interconnects include HyperTransport, RapidIO, and NGIO; all of these interface standards and their operation are well known to those skilled in the art of computer and storage system design. The data bandwidth aggregation occurs in a Cache Access Concentrator 201, implemented as a single chip or module that includes a multiplex/de-multiplex port aggregator with a built in multi-port read cache; the Cache Access Concentrator 201 has one or more storage devices attached via a set of storage interfaces 212, and one or more host systems attached via host interfaces 200, 217.

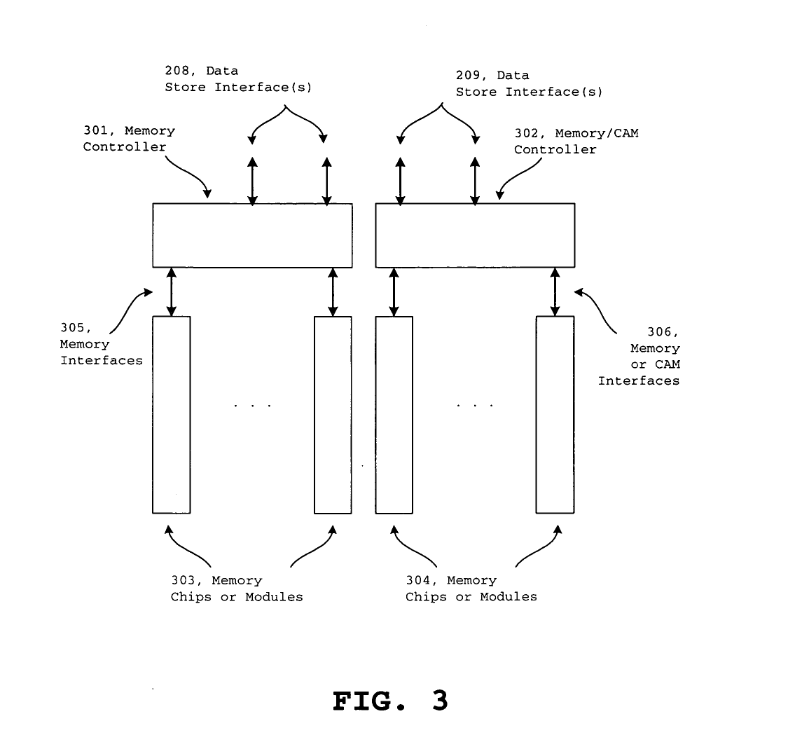

For large read caches, the preferred embodiment of the present invention includes an external data store 210 for caching disk blocks and, optionally, data structures related to the management of the read cache, and a lookup memory 211 for data structures related to block address lookup and cache management; the method of physically storing data tag information in the lookup memory 211 is either based on a content addressable memory (CAM), or standard memory (SRAM or DRAM) with the Cache Access Concentrator 201 utilizing fast search algorithms well known to those skilled in the art of software data structures and searching (hashing, AVL, Red-Black tree, etc). The Data Store Interface for the Main Data Store 210 and the Lookup Memory 211 preferably instantiate the same interface specification for their interfaces 208, 209 as shown in FIG. 3. However the two storages interfaces 208, 209 may be different, and then directly attached to the memory devices through industry standard interfaces for 208 SDRAM, for example, and 209 CAM, for example.

Very large amounts of memory may be attached to the Cache Access Concentrator 201 by employing a hierarchical memory architecture. Devices external to the Cache Access Concentrator 201, such as external memory controllers 301, 302 provide the necessary pins to access large amounts of memory while preserving pins in the Cache Access Concentrator 201. By utilizing a very high speed interface for the memory interfaces 208, 209, such as HyperTransport, RapidIO, 3GIO, SPI4.2, or a similar well known or proprietary link, between the Cache Access Concentrator 201 and an external memory controller 301, 302 more pins become available to connect memory 303 or CAM 304 devices to the controllers 301, 302. Utilizing a hierarchical memory architecture in this way provides a mechanism to attach much more memory to the Cache Access Concentrator 201 than would normally be possible with a given memory interface pin count, with minimal or no performance penalty while incurring the benefit of distributing the power load and pins associated with interfacing to a large number of memory devices. For example, Tera Bytes of SDRAM can be attached easily for read caching of still larger storage arrays. Additionally, multi-porting the controller of an expensive resource, such as Tera Bytes of SDRAM, provides the mechanism to potentially continue to access that resource in the event of a limited failure, for example a failure in one of more than one redundant Cache Access Concentrators 201.

The Cache Access Concentrator 201 has one or more high speed, preferably serial interfaces 220 for the purpose of accessing disk storage through a Write Cache Controller (WCC) 205, 213. Each WCC 205, 213 has one or more disk facing interfaces 206, 219 and one or more controller facing interfaces 203, 204; 215, 216. By way of example, in FIG. 2, the WCC 205, 213 devices have exactly two controller facing interfaces and one disk facing interface, but the present invention accommodates other useful combinations of controller and disk facing interfaces.

The WCC function preferably serves two purposes in addition to that of being a storage write cache dedicated to the attached disk or disks it serves. The WCC also preferably provides dual or multi-porting functionality for the controller interface so as to facilitate controller redundancy; additionally, the WCC also provides power management control for its one or more attached disk drives. The three functions of the WCC, taught herein, may be implemented in one or more devices, through any combination of hardware or software.

Each WCC module can operate autonomously with respect to each other WCC, presenting each Cache Access Concentrator 201 with a multi ported, write cached disk. Additionally, each WCC presents a disk system that is reliable with respect to power faults, where each acknowledged write is guaranteed to be written to its hard disk 207, 218, once an acknowledged write is transacted from the WCC 205, 213 to the Cache Access Concentrator 201, even when the system is subject to a power fault. Any individual hard disk or WCC in the array may fail as a component; this component mode failure is then handled by well known means of RAID or mirroring. The result is that in a fully redundant system, there is no single point of failure that can cause an interruption of service; and in the same system, no power fault mode can cause loss of data if no more than one component fails (or as many component failures as the RAID configuration accommodates) simultaneous with the power fault.

An important advantage of distributing the write buffer into a battery protected space 214 is that the full aggregate bandwidth of all WCC to disk interfaces 206, 219 is utilized in a power fault scenario, tightly bounding the amount of time it takes to flush all of the individual write caches to disk so that no battery backed state needs to be maintained once the last WCC shuts power to its last disk.

Another important advantage of distributing the write cache with power protection is that this architecture scales well as additional WCC modules, with their respective disks, are added to the system.

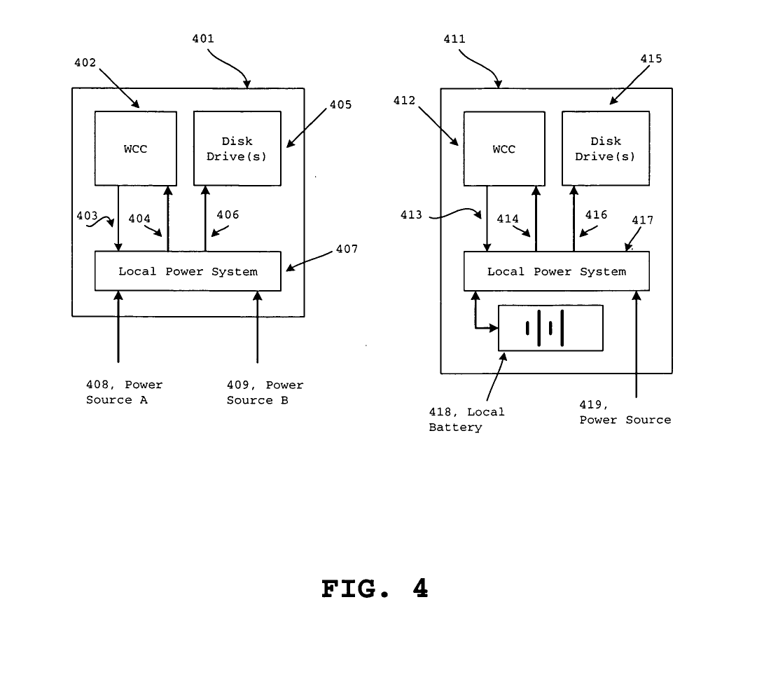

One of two preferred battery protected power distribution architectures for the WCC plus disk drive subsystem 401 is shown in FIG. 4. This power distribution architecture provides two or more redundant power feeds 408, 409 to the Local Power System 407, which in turn feeds power to the WCC 402 and the Disk Drive(s) 405. The WCC 402 controls the power on/off state of the local power domain associated with the subsystem 401. Subsequent to a power on event, the WCC 402 exists reset and enters into normal operation; in the event of a power fault, or a power down command, the WCC flushes its write cache data to its disk(s) and signals the Local Power System 407 to shut down; this event therefore shuts down power to both the WCC and its disk(s). The Local Power System 407 provides all the necessary voltages to the WCC 402 and Disk Drive(s) 405; additionally, the Local Power System 407 generates a power down warning indicator to the WCC 402 when main power is lost. For example Power Source A 408 may be derived from the power mains, while Power Source B 409 may be a system level battery backup supply.

FIG. 4 illustrates a second of two preferred battery protected power distribution architectures 411; this second battery protected power distribution architecture employs a local battery 418 to provide temporary backup power in the event of a power fault. This power protection architecture also provides the system level characteristic of immunity to a single point failure, and may be more convenient in certain embodiments because there is no need for a centralized battery system as in the first power distribution architecture 401. The Local Power System 417 provides all the necessary voltages to the WCC 412 and Disk Drive(s) 415; additionally, the Local Power System 417 generates a power down warning indicator to the WCC 412 when main power is lost.

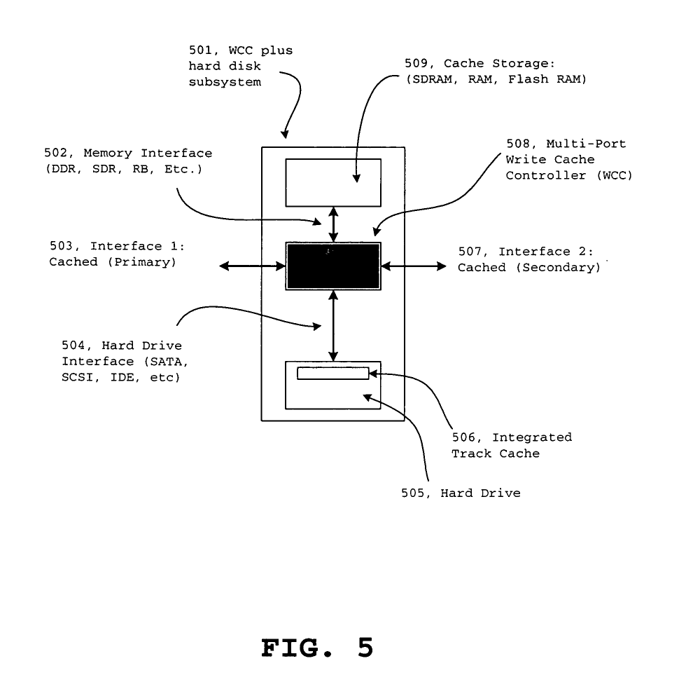

FIG. 5 shows the data path components in a multi-port WCC plus disk drive subsystem. In the preferred embodiment of this invention, the WCC 508 is a single chip device, that preferably utilizes external memory devices 509 for bulk data and data structure storage. Another embodiment would have the WCC function integrated on the same chip with the cache data store, as would be the result of integrating, for example, the WCC module on a DRAM Silicon process with a large DRAM memory. The WCC module preferably utilizes identical, high speed serial interfaces 503, 504, 507, but may optionally interface, for example, with a parallel ATA or SCSI drive, while utilizing serial or parallel interfaces to the controller. The disk drive with WCC subsystem 501 are preferably constructed into a standard, hot swappable module that contains a battery 418 if appropriate.

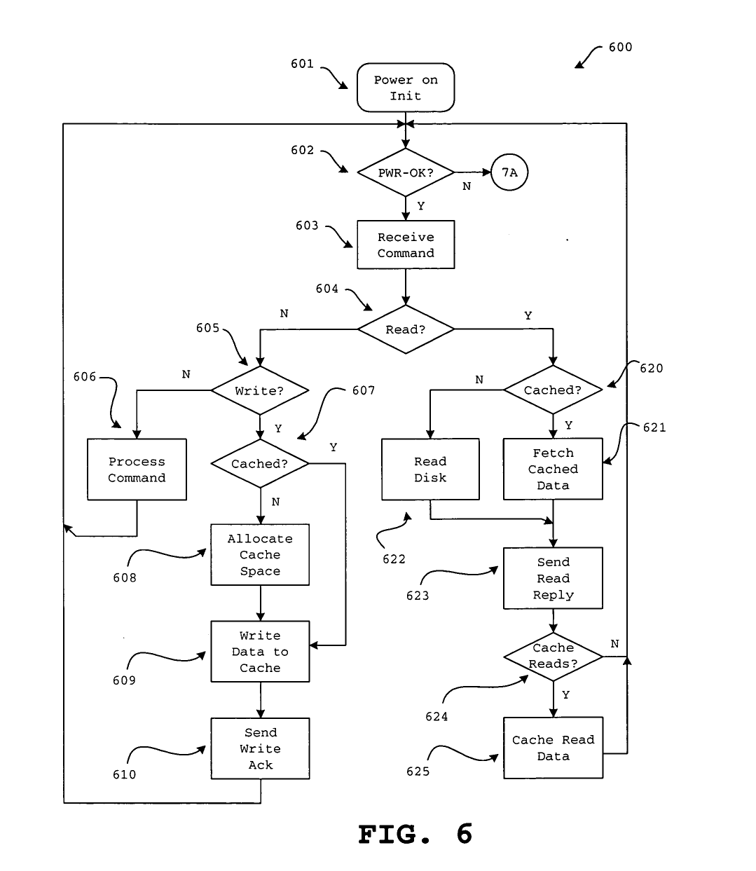

Each WCC instance operates in one of two modes; normal mode and power fault mode. The normal operating mode of the WCC is shown in FIG. 6. In normal operation, the WCC accepts and processes sequential requests, with the command stream grammar, be it a SCSI, ATAPI, or some other storage protocol well known to those skilled in the art of storage systems, being parsed by the WCC module in to read, write, and “other” commands. The category “other” being used for housekeeping, status requests, and other miscellaneous commands. Both read and write requests initiate a query of the currently cached data. As shown in FIG. 6, a read request to data already in the cache (Cached?==“Y”) results in a fast return of data since the data is returned form fast RAM memory rather than disk; in the preferred embodiment of this invention, a read miss results in a regular disk read, with no cache space being allocated for fetched read data. Reads are not cached because the preferred embodiment of this system employs an upstream read cache that statistically covers any recent reads the WCC might hit; thus, unproductive write cache flushing is avoided. Providing cached data on a read is essentially free, since cached read data can be provided with no prospect for performance degradation.

In the absence of an upstream read cache, it may be productive to provide a read caching option in the WCC; this system would have all the benefits of the write cache, and the benefits of a scalable read cache. While the WCC can be utilize to cache reads, the ultimate read cache performance provided by a WCC with explicit read caching may be lower than a read cache function situated closer to the host interface; this situation is due to the additional latency potentially incurred by having to go through an additional interface to get to the read cache.

FIG. 6 illustrates an embodiment of a method of processing a write request in accordance with one or more aspects of the invention. In step 601 a power in initialization is completed. This initialization process includes booting any control logic for the WCC; this control logic may include an embedded microprocessor with some form of operating environment such as an embedded operating system. This initialization step also includes setting up and organizing all the data structures necessary for storing, searching, aging, replacing, and otherwise manipulating cache entries associated with the WCC. In step 602, the Local Power System 407, 417 determines the status of the primary power (i.e., power mains supplied power); the status consists principally of “okay” and “not okay”, whereby “not okay” indicates power loss or sporadic loss from the primary power source. The Local Power System 407, 417 may set a sticky “not okay” status if the primary power source is experiencing transient dropouts. In step 603, the WCC receives a command from one of its interfaces. The WCC then parses the command to determine what action is needed in response to that command. The WCC may optionally queue incoming commands for processing. In steps 604 and 605 the command is determined to be either a read from disk, which flows to 620; a write to disk, which flows to 607, or a non-read and non-write command, which flows to 606. Commands other than reads or writes to disk storage blocks consist typically of read and write commands to non-disk targets; for example a command to read the vendor specific information about a disk, or a shut down command to a disk.

If a write command is received by the WCC for one or more physical disk blocks that have been cached by the WCC, as determined by step 607, but have not yet been written to disk, then those blocks are simply over-written in the cache data store. This over-write operation is somewhat independent from the decision to actually write the blocks to disk. In step 607, a content search/lookup, is used to determine if the incoming write command's block address matches any currently stored block addresses associated with currently cached data. All cache entries are either marked “valid” or “not valid”; upon initialization of the cache in step 601, all entries are marked “not valid” as the search data structure for block addresses is built. A content search of currently valid block addresses may use any of the various appropriate algorithms to perform a Content Addressable Memory operation, including a direct hardware implementation through various hashing or tree-based algorithms.

If the block(s) targeted by a write command are not currently cached in the WCC data store then space must first be allocated, and subsequently the blocks associated with the write command may be written to the cache data store. This allocation step occurs in step 608. Allocating a new cache entry in step 608 involves querying a list of Available cache entries; in this context an Available Cache Entry is a cache entry that is either unused up to the time it is requested and has the “not valid” attribute, or it is a cache entry that is currently holding valid data that has already been stored to disk and is therefore both “valid” and “Available”.

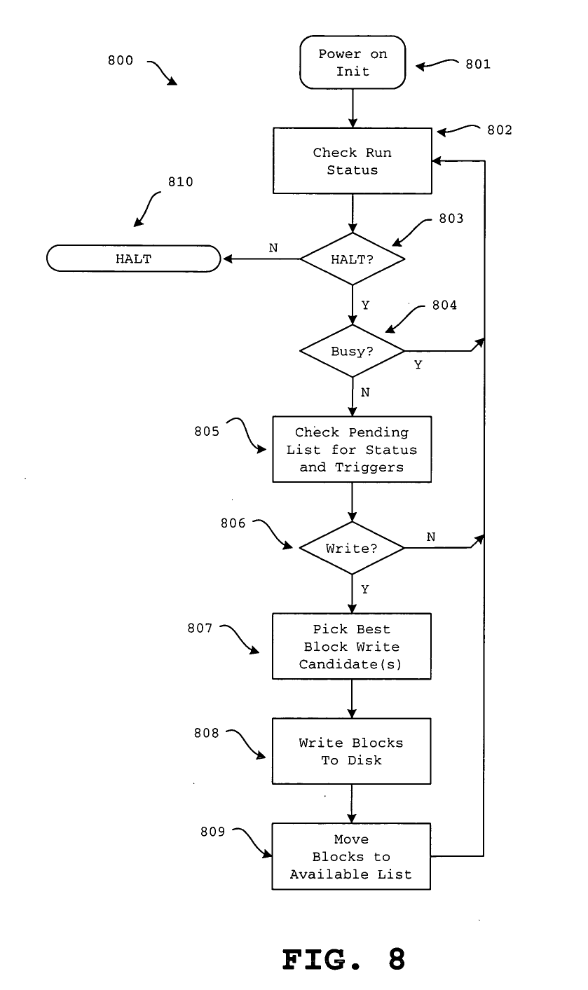

It is important that the write cache always has Available space in which to absorb and cache write command data. If the allocation function does not immediately have an Available Cache Entry in the data store when a write command arrives, then the write operation must block until space can be freed by conducting a time consuming write to disk, thus reducing the efficiency potential of the write cache. Therefore, the WCC must be able to absorb write commands as they arrive with a low blocking probability. The time between write commands is used to flush absorbed write data to disk. If the write command frequency is too high, the write cache performance degenerates to that of an un-cached disk system; fortunately, most applications that involve disk storage produce disk accesses patterns that consist of sporadic writes interleaved with a higher probability of sporadic reads. To facilitate the constant availability of available cache entries, a separate allocation process is kept running in the WCC; this process is shown in FIG. 8.

Step 609 the data contained in the incoming write command is stored in cache. If the disk block address was not present in the cache, then the incoming block address is written to a newly allocated cache entry in an associated block address tag field; the contents of the write command are also written to an associated block data field in the cache element data structure. This newly written cache element is placed in the Pending List. If the incoming disk block address matches an existing entry, either in the Pending List or in the Available List, then that entry containing the newly written data is moved to the Pending List.

In the event of a read command, as determined by Step 604, the associated disk block address is searched against the Pending list and the “valid” entries in the Available list. This search operation occurs in step 620. If the requested block(s) is valid and available in the cache, it is fetched from the cache in step 621 and a reply is prepared. This fetch operation is implementation dependent but may be as simple establishing a pointer to the cache entry for step 623, where a reply to the read request is formed and returned to the requesting port on the WCC. If the requested block data is not cached at the time of the read request, then the requested block data must be read from the disk drive, as shown in step 622; subsequently, a reply is formulated with the read data and returned to the requesting port on the WCC.

In step 624 a determination is made as to whether or not read requests should be cached by the WCC. If reads are not to be cached, then the read operation is complete and the WCC returns to step 602. If reads are to be cached, then the read data just read from disk is to be preserved and entered in the cache. The specific sequence of events may be slightly altered in this path to, for example, concurrently store cached read data during or before the time read data is returned to its requesting port. The act of caching read data potentially displaces cached write data, which may negatively impact system level performance in some instances, especially in those cases where an upstream read cache is present. When an upstream read cache is present, caching reads in the WCC has a high probability of creating redundant copies of the read data in the WCC and therefore reducing the write cache efficiency of the WCC. Since redundant copies of read data are never reused in the WCC, as they get serviced upstream, there is no advantage to caching reads in the WCC if a sufficiently large upstream read cache is present. If no upstream read cache is available, then allowing reads to be cached in the WCC may be advantageous.

The process in FIG. 8 provides a constant movement of cache elements in the Pending List to the Available list; thus, this process maintains the pool of Available Cache Entries in the Available List needed by the process shown in FIG. 6. Step 801 waits for all power on boot processes to complete, then initializes the necessary data structures for use in this process; these include field entries in the cache entries, the Available and Pending list data structures, as well as any disk block scoreboards and disk status data necessary to optimize disk write scheduling.

Alternate embodiments of the processes shown in FIG. 6 and FIG. 8 may move the various initialization steps to other processes, altering the specific boot chronology but not altering the initialization steps themselves.

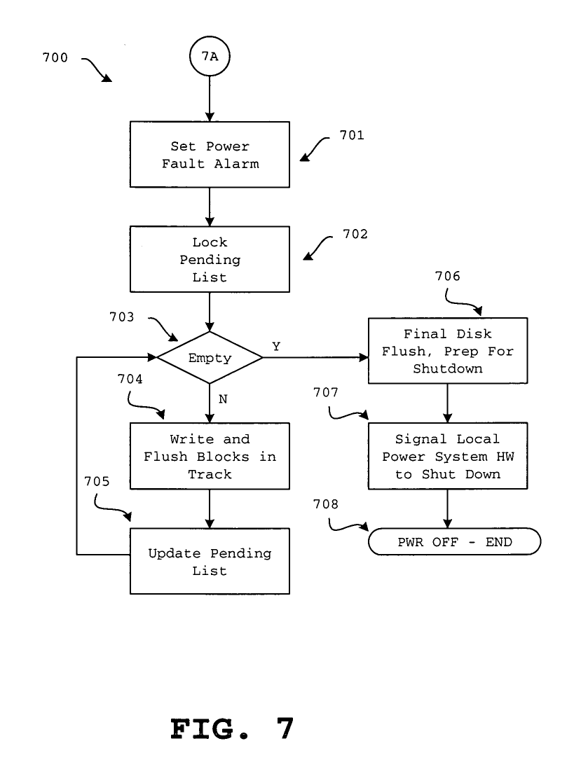

Process 800 necessary for ongoing operation creation of Available List entries and therefore the ongoing operation of the WCC. In the even of a power failure, the WCC must execute a flush of all Pending cache data to disk. Thus Step 802 checks power and disk status; if the process discovers that there is a power fault, then process 800 halts and allows the process shown in FIG. 7 to flush the cache content to disk before powering down its local drive(s) and itself. If there is no power fault, as determined at Step 803 and the disk is not busy, as determined at Step 804, then in Step 805 this process checks to see if there are data blocks in the Pending List that satisfy a write flush criteria. Many strategies are available to Step 805 in determining whether or not to write Pending entries to disk. Step 805 is simply determining if there are entries that meet a criteria; if there are none, then the process loops back and checks status in Step 802.

Example criteria for Step 805 may be to check if there are more than a threshold number of pending block writes collecting on a given track; further more, Step 805 may also require those blocks to be waiting for a minimum amount of time before writing any of the blocks on that track. Another criteria for writing a block may be that it has been waiting in the Pending list longer than a certain threshold of time. Other write criteria are available and known to those skilled in the art of disk storage management.

In Step 806 a determination is made as to whether or not there are any blocks to be written to disk. If there are, then Step 807 picks the best candidates and either initiates disk writes directly to Step 808, or queues the writes to a process responsible for de-queuing and writing them. FIG. 8 shows the direct approach.

Step 809 is responsible for moving blocks from the Pending List to the Available List. Only write requests place cache elements on the Pending List. Once written to disk, these elements may be moved to the Available List. If read caching is permitted, then blocks that have been assigned to store data from a given disk block read operation are kept as valid entries in the Available List. Step 809 must therefore implement a replacement policy for Available List entries. Several strategies are available for cache replacement policies that are well known to those skilled in the art of cache design; Least Recently Used (LRU) replacement is generally quite efficient. In the WCC case, because read and write data are mingled in what is primarily a write cache, a mechanism may be employed to favor cache entries that are moved from the Pending List to the Available List versus cache entries that directly enter the Available List from a read operation. An example strategy may be to split the Available List into two groups: one for reads and one for writes whereby an upper occupation limit is places on the read entries. The LRU replacement policy may then be implemented separately on each of these two groups. If the Available List runs short of elements from the write group, then elements from the read group maybe allocated to incoming writes. Any time a specific block address is written that write data is placed in the Pending List, even if that block is currently cached in the read group.

Step 806 may employ various strategies to select writes in a sequence that will result in maximum disk efficiency and write throughput. For example, Step 807 may preferentially choose blocks from the Pending List that are nearby the current disk head position, minimizing seek time. It should be noted that disk head seek time dominates disk access time, so the less track to track head seeks a disk must undertake, the greater the overall access efficiency. Another possible strategy for Step 807 involves scheduling a general inner to outer traversal and back again of the disk head. Intervening read operations force priority over the background write operations and force the head to the position necessary to service the read, which may be well out of the planned sweep. In this event, Step 807 simply re-computes a new sweep and begins again, always in jeopardy of being preempted by a read. It is possible that certain pathological read accesses patterns in combination with the write access patterns will cause certain, or many, Pending List elements to never be written unless there a scheduling priority applied to those Pending List elements that have pending for over a threshold amount of time. Thus, the appropriate state is kept per Pending List element to track time on the Pending list. Note that when a cache entry that is on the Pending List is re-written, this time can be reset; in fact, it may be advantageous to also require a minimum amount of time on the Pending List before Step 805 is allowed to flag a given element as being eligible to be written to disk. In many applications, there is a high probability of the a given block being written a second or third time in a short span of time once that block has been written once.

Once the block write data associated with a cache entry from the Pending List is written to disk, that cache entry is moved to the Available List.

So long as the WCC writes Pending List elements to disk faster than Available List elements are needed for allocation in Step 608 or Step 625, then writes collected by the WCC can be processed at the interface wire speed, yielding the best possible performance.

FIG. 7 shows the shutdown mode of operation for the WCC. Process 700, an extension of process 600 shown in FIG. 6, is followed by this invention to conduct an orderly system shutdown at the WCC level. The shutdown process is initiated when a power warning is indicated by hardware monitoring and sensed in Step 602; this warning shows up as a “PWR-OK” failure in FIG. 6 and a jump to label 7A in FIG. 7. Once 7A is taken, the system sequentially writes all tracks containing pending writes until the write cache has been completely written to disk. The disk is then instructed to perform a final flush, as some disk drive mechanisms have track write caches 506 that can not be disabled. Finally, the process in FIG. 7 instructs the Local Power System 407, 417 to shut down power to the WCC and its associated disks. At the point where the WCC Local Power System 407, 417 is instructed to shutdown, there is no write state being held by any parts of the system, except for the non-volatile data stored on the attached hard disks.

In Step 701 a power alarm is set; this is a status bit that may be non-volatile so the system will be aware of the previous power fault. In Step 702 the Pending List is locked from accepting further write requests. In Step 703 a determination is made as to whether there are any queued writes in the Pending List. If the Pending List is empty, then Step 706 causes the Disk Drive to follow its own safe shut down procedure; this may include flushing the disk's internal volatile track cache, parking the head(s), and stopping the platter motor. Additionally, in Step 706 the host side ports are also shut down as soon as appropriate. In Step 707 the Local Power System is signaled to shutdown. Finally, the WCC is powered down in Step 708.

In Step 704 the disk head is positioned either on the extreme outside or inside track of data represented in the Pending List once; then, based on which tracks are represented in the Pending List, Step 704 writes all blocks associated with that track.

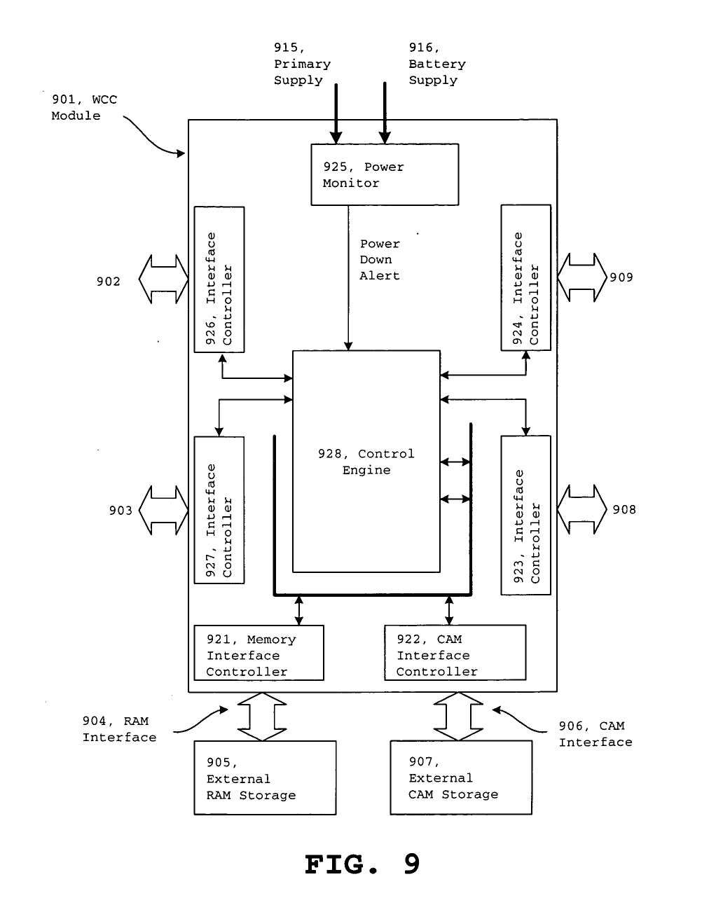

FIG. 9 illustrates an embodiment of the WCC portion of this invention. For purposes of illustration four interfaces 902, 903, 908, 909 are shown, but the invention should not be construed to be limited to four ports, as a number of useful configurations are contemplated with, for example two, three, or five ports. The WCC consists of a Control Engine 928, a Power Monitor interface 925, and memory interfaces for external memory 921, 922.

The WCC illustrated in FIG. 9 shows an integrated power monitoring mechanism 925 on chip with the WCC control logic. This function alerts the Command and Process Engine of a power failure and thus a switch to battery power; this alert initiates the shutdown flush procedure shown in FIG. 7 and prepares the WCC for a complete shutdown. The power monitoring mechanism 925 may be implemented off chip in an alternate embodiment. The Power Monitoring system may also be combined on chip or in the same chip package with the Local Power System 407, 417. The WCC device may receive status as well as power from both the Primary Supply 915 and the Battery Supply 916.

There are two external memory device interfaces 904, 906 shown in FIG. 9. Two memory interfaces provide bandwidth for either high performance memory I/O and thus a high transaction rate, or a larger amount of memory than will fit conveniently on one physical port. If the performance of the WCC warrants an external CAM device to accelerate lookup performance, then one of the memory ports may be used to attach a CAM device 907. Smaller cache sizes with high port rate performance can be achieved using an on chip CAM.

In another embodiment, only one external memory port 904. is necessary to provide the cache data store, as well as all necessary data structures for the WCC. Alternately, this memory may be on chip for smaller cache configurations.

The Control Engine 928 may be implemented with custom built logic, or with an embedded processor running code to implement the various procedures shown in FIG. 6, FIG. 7, and FIG. 8. There are many detailed implementations available for this architecture; implementation techniques for this architecture are well known to those skilled in the art of System On a Chip (SOC) design.

Now that the Write Cache Controller portion of this invention has been taught to the reader, an additional advantage of this distributed write cache architecture which utilizes a plurality of instances of Write Cache Controllers may be explained. First, it should be pointed out that decoupling power fault management from component fault management vastly simplifies the overall design and reliability of a power fault tolerant system. Thus, in the event of a controller failure, because the non-volatile state is held entirely at the WCC level in a protected power domain, the failed controller can relinquish control immediately to a redundant controller; additionally, there is no need to transfer ownership of state for the non-volatile pending-write buffer (held in the WCC's Pending List). There is no need to have redundant controllers constantly sharing state. In fact, the only state lost in a catastrophic controller failure is potentially the read cache state; while this may cause a temporary decrease in the overall performance of the system, such a failure does not cause corruption of any data.

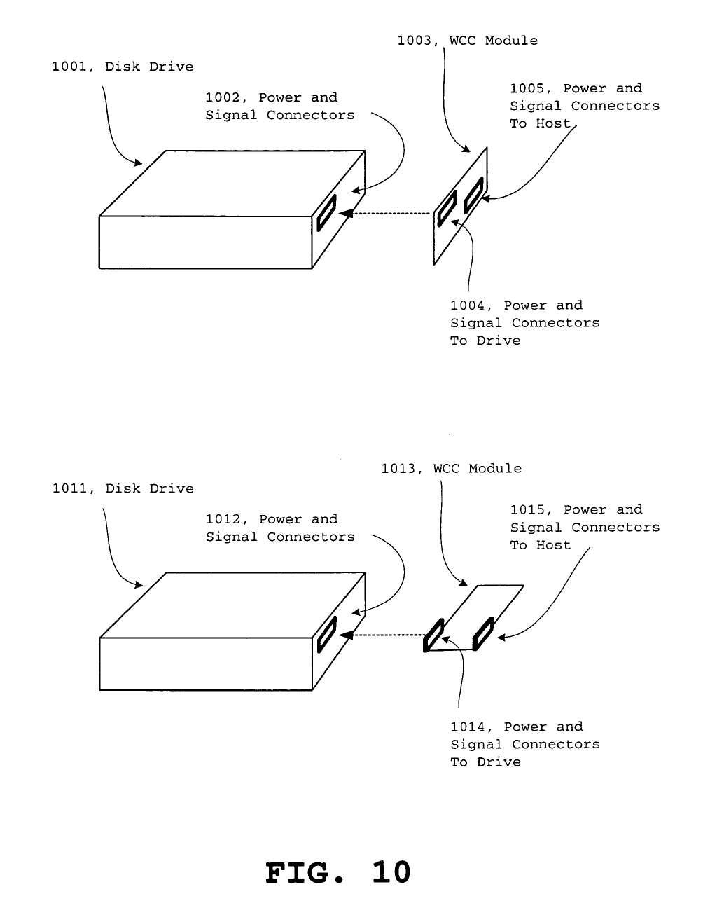

FIG. 10 shows two mounting and connector options for the Write Cache Controller Module, which contains a WCC chip, connectors, and if appropriate, one or more back up batteries. A Disk Drive 1001 which will have power and signal connectors 1002 interfaces to a WCC Module 1003 via the modules disk facing connector 1004. The WCC Module 1003 then interfaces to its one or more host controllers via host facing power and signal connectors 1005. Similarly, WCC Module 1013 interfaces with Disk Drive 1011, except using 90 degree connectors in stead of zero degree connectors. By mechanically binding the WCC Module 1003, 1013 to the Disk Drive 1001, 1011, the combination subsystem can be treated as a commodity, replaceable storage module. These storage modules can then be combined to build RAID shelves with excellent write caching performance while being minimally obtrusive to existing RAID controller designs.

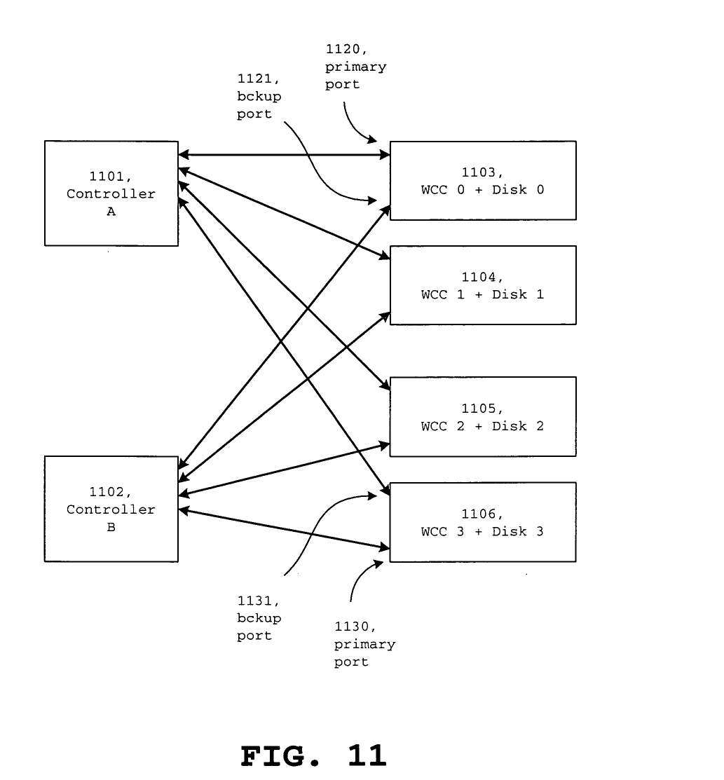

FIG. 11 shows a preferred method of redundant Cache Access Concentrator (CAC) connections, for example, between two CAC controllers 1101, 1102 and four Write Cache Controllers 1103, 1104, 1105, 1106. In the event that any one controller fails, there still exists an active and functional path to all the disks in the disk array. In the event that any one disk or WCC fails, its currently active controller has access to redundant copies of the data otherwise in jeopardy of loss; RAID or mirroring provides this redundancy.

In some controller schemes, primary responsibility is for each disk is divided over the available drives. In such a scenario, Controller A 1101 is, for example, primarily responsible for disks 0 and 1 1103, 1104; while Controller B 1102 is primarily responsible for disks 2 and 3 1105, 1106. In the event that Controller A 1101 fails, Controller B 1102 is notified either by an independent set of watchdogs, or by a vote of WCC units. In an architecture with more than 2 Controller units, a vote of Controllers can also provide the notification to a failed Controller and its WCC units. Note that no write cache state needs to be conveyed between Controller A 1101 and Controller B 1102 to provide reliable write caching that is tolerant of both power and component faults.

If more than one controller needs to have primary read and write access to the same disk then a cache coherency problem may result if both controllers also access the same blocks. This is because each controller's read cache may not be aware of other controller's write activity. In such a case, read cache invalidation information needs to be between Controller A 1101 and Controller B 1102, for example. The path for such data could be directly between the two controllers or via a proprietary data signal emitted from each WCC port except that port that received the write command. The solution to cache coherence in this setting is beyond the scope of this invention, but there exist well known general solutions in the art. Is most storage applications, this issue does not arise because disk blocks are allocated to exclusive control by exactly one controller; that controller may change in the event of a component failure, but there is only ever one controller responsible for a given set of disk blocks.

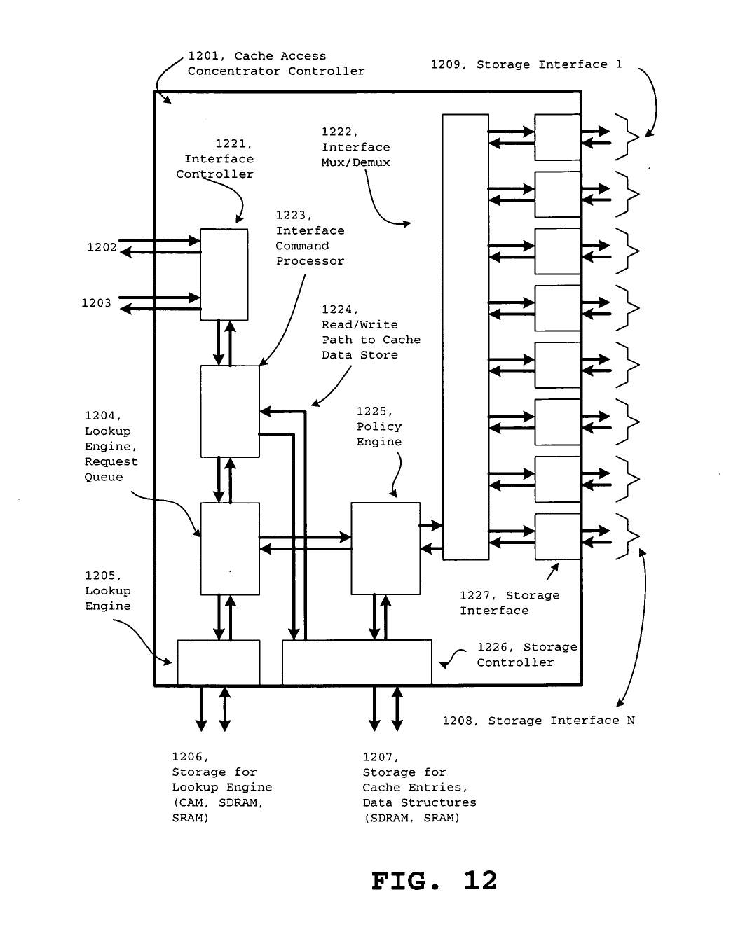

A block diagram of the Cache Access Concentrator 201 is shown in FIG. 12. Host read, write, and system management commands are parsed by methods well known to those skilled in the art of storage protocols in the Interface Controller 1221; these protocols include, for example SCSI and ATAPI, and transport protocols such as Fiber Channel. These commands result in protocol agnostic commands for read and write that are then executed by the Interface Command Processor 1223. Write commands are passed through to the Interface Mux/Demux 1222. Additionally, write requests are posted to the read cache; if the target block address is not currently cached, a new entry is allocated and written but not made available until the disk drive acknowledges the write; if the target address is present in the cache element Replacement List then the write gets posted but an overwrite of the presented read cached block only occurs after write is acknowledged by the disk drive, prior to that the previous version is presented to a read request. The Replacement List is similar to Available List used in the WCC, with the exception that read allocations for future reads are treated equally with write allocations for future reads. The Replacement List is list of “valid” or “not valid” cache elements that are ordered in terms of their request order age; an LRU replacement policy can simply take the oldest element on the list to choose an entry for a new data allocation.

The read cache in the Cache Access Concentrator does not have a write Pending List, but does have a Read Pending List; the Read Pending List contains read request block addresses and cache element data store allocation information for reads that are posted to one of the Storage Interfaces 1209, 1208 (1 . . . N) but not yet returned.

When a read request is posted to the read cache a lookup mechanism, provided by the Lookup Engine 1205, determines if the target address is currently cached; if so, the read request is serviced and a reply packet is generated and returned. If the requested data is not present, a read request is forwarded to the disk drive. When the disk drive replies with data, that data is stored in a location determined by an Available List management mechanism, such mechanisms are well known to those skilled in the art of general caching. The Policy Engine 1225 implements the replacement policy for Available and Occupied block lists.

In a preferred implementation, external bulk semiconductor memory is accessed through an interface port 1207; this memory stores block data as well as the necessary data structures for accessing and managing the data. Alternately, an additional port 1206 provides access to selected data structures. Additionally, this second port 1206 serves as the access to content addressable memory (CAM), also implemented on external devices. If the throughput goals are attainable by using SRAM or DRAM structures to contain and search the block address tag database, then CAM devices may not be needed in favor of cheaper SRAM or DRAM.

The Mux/Demux function 1222 serves as the on chip data router and operates on several requests simultaneously. One or more Storage Interfaces 1227 connect the controller to a plurality of write cache controllers that manage one or more disk drives.

What is claimed is:

1. A data storage caching system, comprising:
a cache access concentrator configured to accept storage requests from a host interface; and
a write cache controller coupled to the cache access concentrator and configured to accept requests from the cache access concentrator.

2. The data storage caching system of claim 1, wherein the cache access concentrator is configured to accept storage requests from additional hosts.

3. The data storage caching system of claim 1, wherein the cache access concentrator is configured to pass write requests to the attached distributed write cache comprised of at least one write cache controller.

4. The data storage caching system of claim 1, wherein the write cache controller is coupled to at least one disk drive.

5. The data storage caching system of claim 1, wherein the write cache controller is coupled to at least one battery backed power source that provides sufficient power to flush all cached write data to disk in the event of a power outage.

6. A data storage caching system comprising:
a write cache controller system configured to accept storage request from a host interface; and
a controller device coupled to a hard disk; and
a controller device coupled to a backup battery power system; and
a controller system coupled to memory for storing cache entries;

7. The data storage caching system of claim 6, wherein the write cache controller is coupled to at least one disk drive in a single mechanical module.

8. The data storage caching system of claim 6, wherein the write cache controller is coupled more than one host adaptor and provides multi-ported access to a single ported hard disk.

9. A method for caching disk read and write requests in a distributed cache system, comprising:
caching the write requests at interface speed through a write cache controller into a battery protected memory;
scheduling cached write data to be written to disk from battery backed memory; and
writing the previously cached write data to disk, thus completing the already acknowledged write transaction to disk while making cache entries available for future incoming write commands.

10. The method of claim 9, further comprising:
creating a pool of available cache entries to accommodate new write commands.

11. The method of claim 9, further comprising:
responding to read requests for data previously requested and currently in cache;

12. The method of claim 9, further comprising:
acknowledging a write request once it has been cached in the battery protected memory;

13. The method of claim 9, further comprising:
flushing all of the write cache contents to the disk in the event of a power failure before shutting down the disk drive

14. The method of claim 13, wherein the flushing preserves the integrity of all acknowledged writes.

15. A data storage caching system, comprising:
means for caching the write requests at interface speed in a battery protected memory;
means for scheduling cached write data to be written to a disk; and
means for writing the cached write data to the disk.

16. The data storage caching system of claim 15, further comprising:
means for creating a pool of available cache entries to accommodate new write commands.

17. The data storage caching system of claim 15, further comprising:
means for responding to read requests for data previously requested and currently in cache;

18. The data storage caching system of claim 15, further comprising:
means for acknowledging a write request once it has been cached in the battery protected memory;

19. The data storage caching system of claim 15, further comprising:
means for flushing all of the write cache contents to the disk in the event of a power failure before shutting down the disk drive

20. The data storage caching system of claim 19, wherein the flushing preserves the integrity of all acknowledged writes.
